(19) United States
(12) Patent Application Publication
(10) Pub. No.: US 2025/0018502 A1
(43) Pub. Date: Jan. 16, 2025

(54) LASER LIGHT CORRECTION METHOD

(71) Applicant: Tokyo Seimitsu Co., Ltd., Tokyo (JP)

(72) Inventors: Chikara AIKAWA, Tokyo (JP); Satoru IWAKI, Tokyo (JP)

(73) Assignee: Tokyo Seimitsu Co., Ltd., Tokyo (JP)

(21) Appl. No.: 18/898,913

(22) Filed: Sep. 27, 2024

Related U.S. Application Data
(63) Continuation of application No. PCT/JP2023/010047, filed on Mar. 15, 2023.

(30) Foreign Application Priority Data
Mar. 29, 2022 (JP) 2022-054295

(51) Int. Cl. B23K 26/046; B23K 26/067

(52) U.S. Cl. CPC B23K 26/046; B23K 26/067

(57) ABSTRACT

The laser light correction method includes: a step of performing trimming machining on a positioning workpiece in which a laser irradiation surface includes a material that facilitates detection of a laser-irradiation mark, the trimming machining in which a split laser is focused on the laser irradiation surface via a laser optical system while moving the laser optical system in the machining feed direction relative to the positioning workpiece to form a first groove having two rows parallel to each other in a machining feed direction, and performing hollowing machining in which a line laser is focused on the laser irradiation surface via the laser optical system to form a second groove; a step of detecting the first groove and the second groove by a microscope; and a step of correcting focus positions of the split laser and the line laser based on detection results of the first and second grooves.

### CROSS-REFERENCE TO RELATED APPLICATIONS

The present application is a Continuation of PCT International Application No. PCT/JP2023/010047 filed on Mar. 15, 2023 claiming priority under 35 U.S.C § 119(a) to Japanese Patent Application No. 2022-054295 filed on Mar. 29, 2022. Each of the above applications is hereby expressly incorporated by reference, in its entirety, into the present application.

### BACKGROUND OF THE INVENTION

### Field of the Invention

The present invention relates to a laser light correction method and particularly relates to a laser light correction method in a laser machining device that irradiates a wafer with laser light to perform laser machining.

### Description of the Related Art

In a manufacturing field of a semiconductor device, there has been a wafer (semiconductor wafer) on which devices are formed of a stacked body which is obtained by stacking a low dielectric constant insulator film (Low-k film) and a functional film that forms circuits on a surface of a substrate such as silicon. On such a wafer, grid-shaped streets partition the devices in a grid shape, and individual devices are manufactured by dividing (dicing) the wafer along scheduled dividing lines.

The Low-k film has a nature of being fragile and susceptible to falling off, and thus, in some cases, the Low-k film may fall off in dicing the wafer with a blade, resulting in damages on the devices. To address such a nature of the Low-k film of being fragile and susceptible to falling off, a method is known in which two rows of a first groove that divide the Low-k film are formed on both sides of a scheduled dividing line with laser ablation machining, and thereafter a second groove is formed between the two rows of the first groove (for example, Patent Literature 1).

In laser ablation machining, two types of laser light are used: a split laser having a split-shape which is used to form the first grooves; and a line laser having a line shape which is used to form the second groove. In such laser ablation machining, when there is only one condenser lens, the shape of the laser light is switched between the split laser and the line laser, which may cause a displacement of a focus position on the wafer. On the other hand, when there are two or more condenser lenses, although it is not necessary to switch the shape, displacement in relative positions of the condenser lenses may cause displacement of the focus position on the wafer. When the focus position is displaced on the wafer, machining quality deteriorates, which makes it necessary to adjust the focus position of the two types of laser light.

In relation to the problem, Patent Literature 1 discloses a method for correcting the positions of the first grooves and the second groove, in which the first groove is formed at a scheduled dividing line in a device region of the wafer and the second groove is formed at a scheduled dividing line in an outer circumference excess region of the wafer.

### CITATION LIST

### Patent Literatures

Patent Literature 1: Japanese Patent Application Laid-Open No. 2015-154009

### SUMMARY OF THE INVENTION

In the method described in Patent Literature 1, because the outer circumferential excess region of the wafer is machined. Therefore, when the positions of the split laser and the line laser are displaced from each other, some laser grooves may be formed into an inappropriate shape. The presence of inappropriately shaped laser grooves may cause uneven blade wear during blade machining after laser ablation machining.

Further, depending on wafers, it may be difficult to detect the positions of the laser grooves due to the influence of patterns or debris. In such wafers, the focus position of the laser light may not be appropriately corrected.

The present invention has been made in view of such circumstances, and aims to provide a laser light correction method capable of accurately correcting the positions of a split laser and a line laser.

In order to solve the above problems, a laser light correction method according to a first aspect of the present invention includes: a step of performing trimming machining on a positioning workpiece in which at least a laser irradiation surface includes a material that facilitates detection of a laser-irradiation mark, the trimming machining in which a split laser is focused on the laser irradiation surface via a laser optical system while moving the laser optical system in the machining feed direction relative to the positioning workpiece to form a first groove having two rows parallel to each other in a machining feed direction, and performing hollowing machining in which a line laser is focused on the laser irradiation surface via the laser optical system to form a second groove; a step of detecting the first groove and the second groove by a microscope; and a step of correcting focus positions of the split laser and the line laser based on detection results of the first groove and the second groove.

A second aspect of the present invention relates to the laser light correction method according to the first aspect, in which the positioning workpiece is a wafer with a polyimide film or alignment paper.

A third aspect of the present invention relates to the laser light correction method according to the first or second aspect, in which during the trimming machining and the hollowing machining, one of the split laser and the line laser is caused to scan the laser irradiation surface in the machining feed direction, and another of the split laser and the line laser is caused to scan the laser irradiation surface in an oblique direction with respect to the machining feed direction.

A fourth aspect of the present invention relates to the laser light correction method according to the first or second aspect, in which the split laser and the line laser are caused to focus on the positioning workpiece as single pulse lasers.

A fifth aspect of the present invention relates to the laser light correction method according to any of the first to fourth aspects, in which an overlapping ratio between the split laser and the line laser on the laser irradiation surface is set to zero.

A sixth aspect of the present invention relates to the laser light correction method according to any of the first to fifth aspects, in which at least two alignment marks are formed on the positioning workpiece in the machining feed direction, and the focus positions of the split laser and the line laser are corrected based on detection results of the alignment marks, and the first groove and the second groove.

A seventh aspect of the present invention relates to the laser light correction method according to any of the first to sixth aspects, in which the positioning workpiece is held on a sub-table different from a table for holding a workpiece to be machined.

The present invention makes it possible to accurately correct the positions of the split laser and the line laser.

### BRIEF DESCRIPTION OF THE DRAWINGS

FIG. 1 is a schematic view of a laser machining device according to one embodiment of the present invention.

FIG. 2 is a plan view of a wafer to be machined.

FIG. 3 is an explanatory diagram for explaining laser machining along an odd-numbered street.

FIG. 4 is an explanatory diagram for explaining laser machining along an even-numbered street.

FIG. 5 is a plan view illustrating arrangement of a table and a sub-table.

FIG. 6 is a plan view illustrating an example in which trimming machining and hollowing machining are performed on a positioning workpiece W2.

FIG. 7 is an enlarged view of a VII part of FIG. 6.

FIG. 8 is a diagram for describing a laser light correction method according to an example 1.

FIG. 9 is a plan view illustrating a positioning workpiece according to an example 2.

FIG. 10 is a diagram for describing a laser light correction method according to an example 3.

### DESCRIPTION OF THE EMBODIMENTS

Hereinafter, an embodiment of a laser light correction method according to the present invention is described based on the accompanying drawings.

### Laser Machining Device

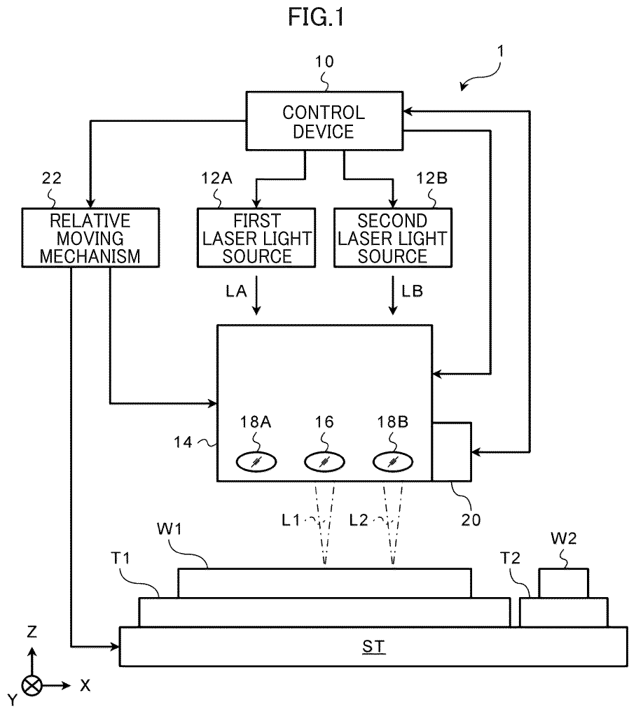

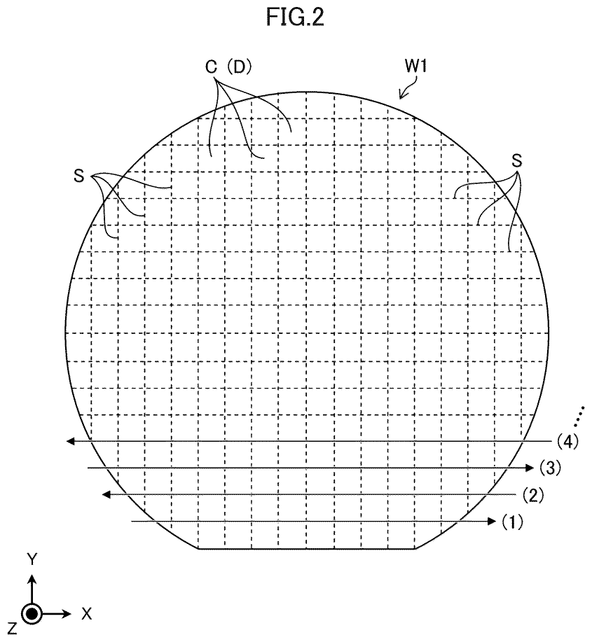

FIG. 1 is a schematic view of a laser machining device according to one embodiment of the present invention. As illustrated in FIG. 1, a laser machining device 1 performs laser machining (ablation grooving) on a wafer W as a preprocess prior to dividing the wafer W1 into chips C (see FIG. 2). Note that X, Y and Z directions in the drawing are perpendicular to each other. Among these directions, the X direction and the Y direction are horizontal directions, and the Z direction is a vertical direction. Here, the X direction corresponds to a machining feed direction of the present invention.

FIG. 2 is a plan view of the wafer W1 to be machined. As illustrated in FIG. 2, the wafer W1 is a stacked body in which a Low-k film and a functional film that forms a circuit are stacked on a surface of a substrate such as silicon. The wafer W1 is partitioned into regions by streets S (scheduled dividing lines) arranged in a grid shape. A device D that constitutes the chip C is provided in each of the partitioned regions.

The laser machining device 1 performs laser machining on the wafer W1 along the streets S for each street S as indicated in bracketed numbers (1) to (4), . . . , in the drawing so as to remove the Low-k film, and the like, on the substrate.

In this event, the laser machining device 1 alternately switches a relative moving direction for moving a laser optical system 14, which will be described later, relatively to the wafer W1 in the X direction for each street S to reduce a takt time required for laser machining of the wafer W1.

For example, in a case where laser machining is performed along odd-numbered streets S indicated by the bracketed numbers (1), (3), . . . , in the drawing, the laser optical system 14 is moved toward an outward direction X1 that is one direction along the X direction relative to the wafer W1. On the other hand, in a case where laser machining is performed along even-numbered streets S indicated by the bracketed numbers (2), (4), . . . , in the drawing, the laser optical system 14 is moved toward an opposite direction along the X direction, that is, in a return direction X2 that is opposite to the outward direction X1 relative to the wafer W1.

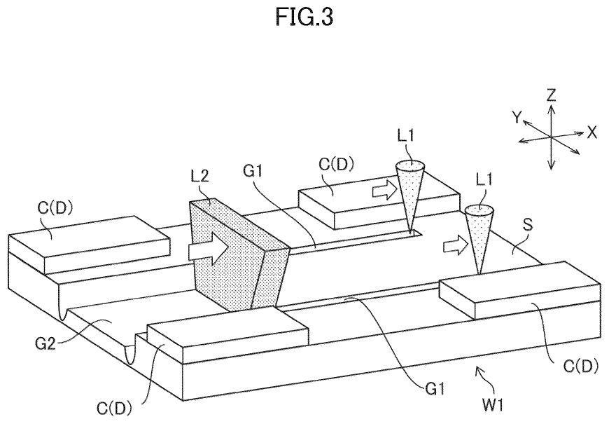

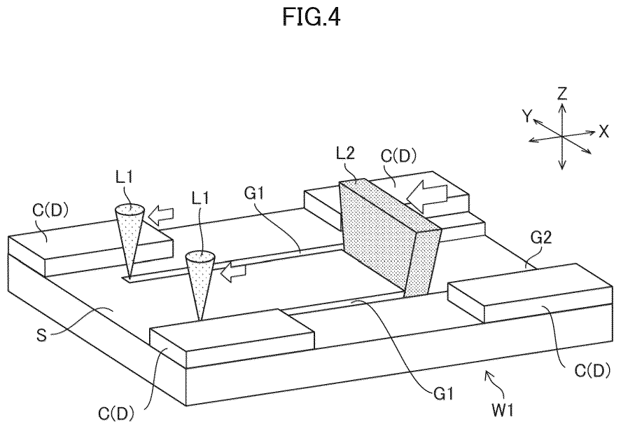

FIG. 3 is an explanatory diagram for explaining laser machining along the odd-numbered street S. FIG. 4 is an explanatory diagram for explaining laser machining along the even-numbered street S.

As illustrated in FIG. 3 and FIG. 4, in the present embodiment, trimming machining and hollowing machining are performed at the same time (in parallel) as laser machining. The trimming machining is laser machining to be performed using two beams of first laser light (split laser) L1 and laser machining of forming a trimming groove G1 (two rows of a first groove, ablation grooves) which is comprised of two rows parallel to each other along the street S.

The hollowing machining is laser machining of forming a hollow groove G2 (second groove, ablation groove) between the two rows of the trimming groove G1 formed through the trimming machining. In the present embodiment, the hollowing machining is performed using second laser light (line laser) L2 having a radius greater than a radius of the two beams of the first laser light L1.

In the laser machining device 1, in either case where the laser optical system 14 is moved in the outward direction X1 or moved in the return direction X2 relative to the wafer W1, the trimming machining is performed prior to the hollowing machining.

As illustrated in FIG. 1, the laser machining device 1 includes a control device 10, a first laser light source 12A, a second laser light source 12B, the laser optical system 14, a microscope 20, and a relative moving mechanism 22.

As shown in FIG. 1, two tables (table T1 and sub-table T2) are installed on a stage. The wafer (product workpiece) W1 to be machined is loaded and held on the table T1. The positioning workpiece (workpiece for positioning) W2 is loaded and held on the sub-table T2.

In the present embodiment, the positioning workpiece W2 held on the sub-table T2 is laser machined using first laser light L1 and second laser light L2 to correct displacement of a machining position.

Here, preferably, at least a laser irradiation surface (surface) of the positioning workpiece W2 includes a material that facilitates detection of a laser-irradiation mark (groove). As the positioning workpiece W2, for example, a wafer (for example, a silicon wafer) with a polyimide film or alignment paper (for example, burn paper or laser thermal paper) may be used. Further, as the positioning workpiece W2, a workpiece in which a surface to be irradiated with laser has a high-reflectivity may be used. For example, a workpiece with a mirror finished surface may be used.

A stage ST moves along the X direction and the Y direction by the relative moving mechanism 22 and rotates around the Z axis under control of the control device 10.

The first laser light source 12A emits laser light LA that is pulse laser light that satisfies conditions (such as a wavelength, a pulse width and a repetition frequency) appropriate for trimming machining to the laser optical system 14. The second laser light source 12B emits laser light LB that is pulse laser light that satisfies conditions (such as a wavelength, a pulse width and a repetition frequency) appropriate for hollowing machining to the laser optical system 14.

The laser optical system 14 forms two beams of first laser light L1 for trimming machining based on the laser light LA from the first laser light source 12A. Further, the laser optical system 14 forms one beam of second laser light L2 for hollowing machining based on the laser light LB from the second laser light source 12B. Then, the laser optical system 14 emits (radiates) the two beams of the first laser light LI toward the street S from a first condenser lens 16. Further, the laser optical system 14 selectively emits (radiates) the second laser light L2 toward the street S from a second condenser lens 18A or 18B under control of the control device 10.

Still further, the laser optical system 14 is moved in the Y direction and the Z direction by the relative moving mechanism 22 under control of the control device 10.

The microscope 20 is fixed at the laser optical system 14 and moves integrally with the laser optical system 14. The microscope 20 captures an image of an alignment reference (not illustrated) formed on the wafer W1 before the trimming machining and the hollowing machining. Further, the microscope 20 captures an image of the two rows of the trimming groove G and the hollow groove G2 formed along the street S by the trimming machining and the hollowing machining. The captured images (image data) captured by the microscope 20 are output to the control device 10 and displayed at a monitor (not illustrated) by the control device 10.

The relative moving mechanism 22, which includes an XYZ actuator and a motor, moves the stage ST in the X and Y directions, rotates the stage ST around a rotational axis and moves the laser optical system 14 in the Z direction under control of the control device 10. This enables the relative moving mechanism 22 to move the laser optical system 14 relative to the stage ST and the wafer W1. Note that, as long as the laser optical system 14 may be moved in the respective directions (including rotation) relative to the stage ST (wafer W1), a relative moving method is not particularly limited.

The relative moving mechanism 22 is driven so as to perform position adjustment (alignment) of the laser optical system 14 with respect to a machining start position that is one end of the street S of the machining target, and relative movement of the laser optical system 14 in the X direction (the outward direction X1 or the return direction X2) along the street S. Further, the relative moving mechanism 22 is driven to rotate the stage ST by 90 degrees, so that each street S along the Y direction of the wafer W1 may be made parallel to the X direction that is the machining feed direction.

The control device 10 is, for example, constituted with a personal computer. The control device 10 includes various kinds of processors (such as, for example, a central processing unit (CPU) and a graphics processing unit (GPU)), a memory and a storage device. Note that various kinds of functions of the control device 10 may be implemented by one processor or may be implemented by the same type or different types of processors. The control device 10 comprehensively controls operation of the first laser light source 12A, the second laser light source 12B, the laser optical system 14, the microscope 20, the relative moving mechanism 22, and the like.

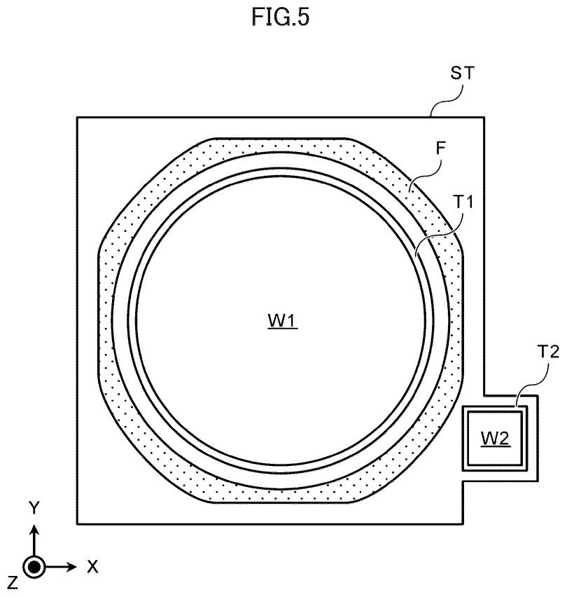

FIG. 5 is a plan view illustrating arrangement of the table T1 and the sub-table T2. As shown in FIG. 5, in the present embodiment, the sub-table T2 for holding the positioning workpiece W2 is provided in the vicinity of the table T1 for holding the wafer W1 to be machined. Note that a reference character F indicated in FIG. 5 denotes a frame for holding the wafer W1.

In the example shown in FIG. 5, the sub-table T2 is provided on the stage ST and is movable along with the table T1, though the present invention is not limited to this example. The sub-table T2 may not be provided on the stage ST and may be movable independently of the table T1.

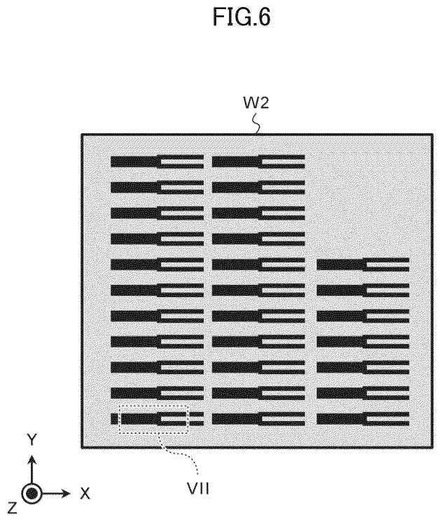

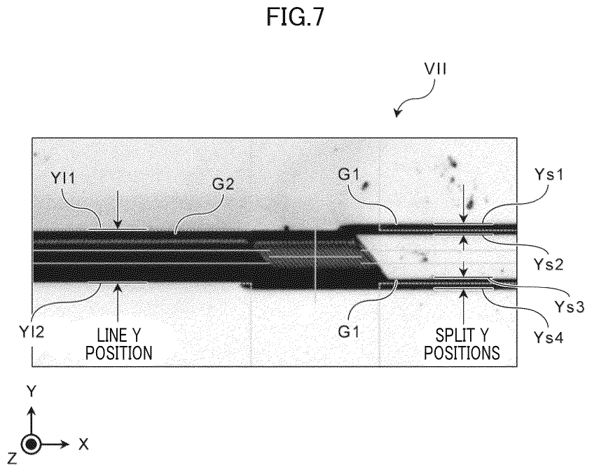

FIG. 6 is a plan view illustrating an example in which the trimming machining and the hollowing machining are performed on the positioning workpiece W2, and FIG. 7 is an enlarged view of a VII part of FIG. 6.

In a case of performing position correction, firstly, the trimming machining and the hollowing machining are performed for the surface of the positioning workpiece W2, so as to form the two trimming grooves G1 and the hollow groove G2 along the X direction.

The microscope 20 is used next to capture an image of the two trimming grooves G1 and the hollow groove G2, and the control device 10 detects the positions of the two trimming grooves G1 and the hollow groove G2 in the Y direction (Split Y positions and Line Y position).

The control device 10 then adjusts the laser optical system 14 based on the detection results of the Split Y positions and the Line Y position. In other words, the irradiation positions of the first laser light (split laser) L and the second laser light (line laser) L2 are adjusted so that the hollow groove G2 (Line Y position) fits between the two trimming grooves G1 (Split Y positions) and partially overlaps with the two trimming grooves G1. As indicated in FIG. 7, the irradiation positions of the first laser light (split laser) L1 and the second laser light (line laser) L2 are adjusted so that Ys1>Ul1>Ys2 and YTs3>Yl1>Ys4 are satisfied, in which Ys1, Ys2, Ys3 and Ys4 represent Y coordinates of respective edge parts of the two trimming grooves G1, and Y11 and Y12 represent Y coordinates of the edge parts of the hollow groove G2.

Here, in the position correction of the laser light, in addition to the irradiation positions of the first laser light L1 and the second laser light L2, a beam diameter or intensity of the second laser light L2 may be adjusted to adjust the width of the hollow groove G2.

According to the present embodiment, it is possible to prevent the wafer W1 to be machined from being machined in the state where the focus position of the first laser light (split laser) L1 and the focus position of the second laser light (line laser) L2 are displaced.

Further, in the present embodiment, since the workpiece that facilitates detection of the grooves formed by the first laser light (split laser) L1 and the groove formed by the second laser light (line laser) L2 may be selected as the positioning workpiece W2, the displacement of the focus positions may reliably be detected.

Note that in the laser light correction method according to the present embodiment, following examples 1 to 3 may be combined and applied.

### EXAMPLE 1

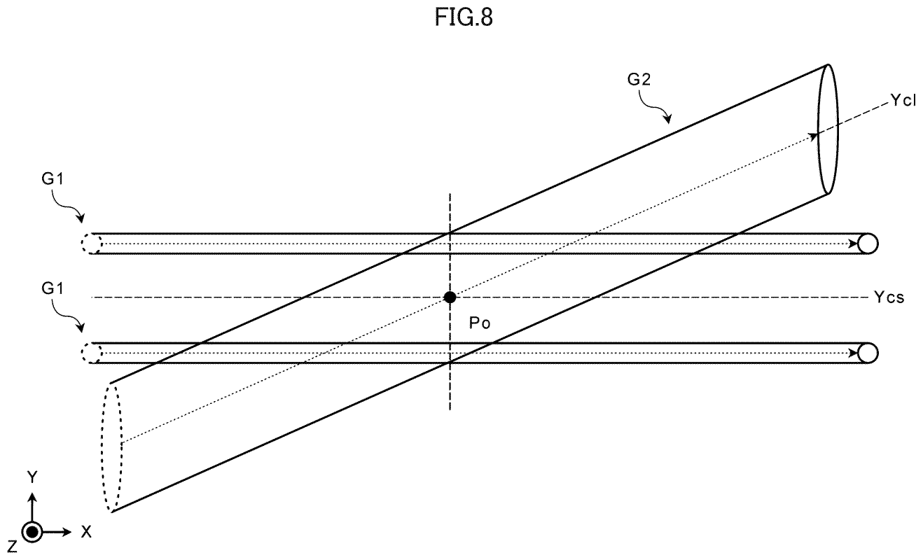

FIG. 8 is a diagram for describing a laser light correction method according to the example 1.

In the example 1, at the time of machining the positioning workpiece W2, the second condenser lens 18A or 18B is moved in the Y direction so that the second laser light (line laser) L2 scans the positioning workpiece W2 in the Y direction to perform diagonal cutting.

Next, the microscope 20 is used to capture an image of the two trimming grooves G1 and the hollow groove G2 to detect the positions of the two trimming grooves G1 and the hollow groove G2. Then, a Y direction position Yo of the second condenser lens 18A or 18B is obtained at a point Po where an equidistant line (center line) Yes between the two trimming grooves G1 intersects a center line Yc1 of the hollow groove G2.

At the time of machining the wafer W1, the Y-direction positions of the second condenser lens 18A and 18B are matched (aligned) with Po. Thereby, it is possible to prevent the wafer W1 to be machined from being machined in the state where the focus position of the first laser light (split laser) L1 and the focus position of the second laser light (line laser) L2 are displaced.

Note that in a case of performing diagonal cutting, it is not necessary to parallelly perform the trimming machining and the hollowing machining. For example, after the first laser light (split laser) L1 is formed along the X direction, diagonal cutting may be performed while the second condenser lens 18A or 18B or an illumination optical system 14 is moved.

Conversely from the above example, the hollow groove G2 may be formed along the X direction and then the two trimming grooves G1 may be formed by diagonal cutting.

### EXAMPLE 2

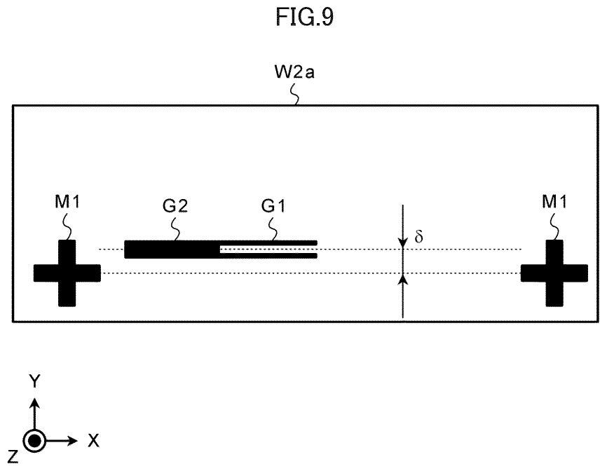

FIG. 9 is a plan view illustrating a positioning workpiece according to the example 2.

As a positioning workpiece W2a in the example 2, a workpiece W2a in which alignment marks M1 are formed is used. In the example shown in FIG. 9, the alignment marks M1 are in a cross shape and are formed at least as one pair (two alignment marks).

In a case of performing laser irradiation position correction, the trimming machining and the hollowing machining are performed to form the two trimming grooves G1 and the hollow groove G2 in a state where an array direction of the pair of alignment marks M1 is matched with the machining feed direction (X direction) by the relative moving mechanism 22. Then, a Y-direction displacement amount 8 between a line segment connecting the pair of alignment marks M1, and a center line of the two trimming grooves G1 and the hollow groove G2 along the X-direction, is calculated. Then, the irradiation positions of the first laser light (split laser) L1 and the second laser light (line laser) L2 are corrected based on the Y-direction displacement amount 8.

When the positioning workpiece W2a is a wafer with a polyimide film, the alignment marks M1 may be formed by, for example, removing parts of the polyimide film. When the positioning workpiece W2a is alignment paper, the alignment marks M1 may be formed by, for example, printing.

According to the example 2, using the positioning workpiece W2a with alignment marks, it is possible to measure and correct the amount of displacement between a machining target position and an actual machining position, in addition to the relative positions of the first laser light (split laser) L1 and the second laser light (line laser) L2.

### EXAMPLE 3

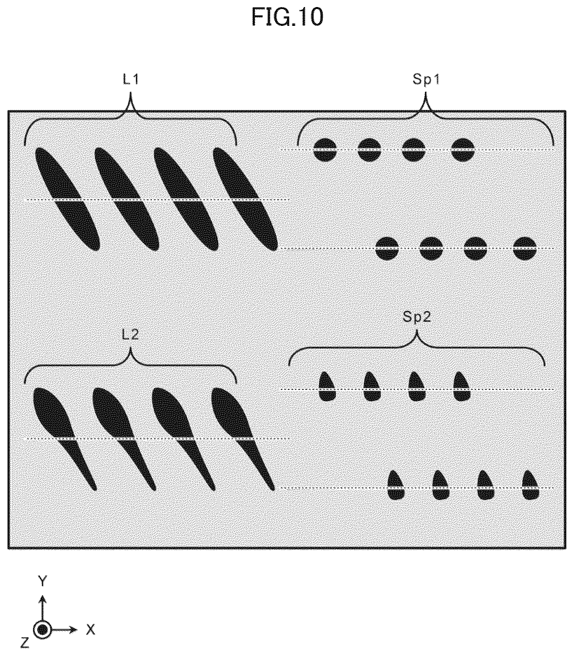

FIG. 10 is a diagram for describing a laser light correction method according to the example 3.

In the example 3, at the time of machining the positioning workpiece W2, machining is performed by irradiating the workpiece W2 with single pulse lasers as the first laser light (split laser) L1 and the second laser light (line laser) L2, or by setting an overlapping ratio of the first laser light L1 and the second laser light L2 to zero. As a result, as shown in FIG. 10, it is possible to examine the two-dimensional machining shape which may be formed by one pulse of each laser light, in advance.

FIG. 10 shows an example in which single-pulse first laser light L1 and single-pulse second laser light L2 are radiated in a state where the overlapping ratio of the irradiation positions of the first laser light L1 and the second laser light L2 is set to zero.

Reference numerals Sp1 and Sp2 in FIG. 10 indicate examples of irradiation with single pulse laser as the first laser light L1, and the reference numerals L1 and L2 indicate examples of irradiation with single pulse laser as the second laser light L2.

As shown in FIG. 10, in the examples Sp1 and L1, the machining shape of each machining mark by one pulse of laser is roughly symmetrical with respect to a center (center of gravity) of each machining mark.

Contrary to this, in the examples Sp2 and L2, the machining shape of each machining mark by one pulse of laser is asymmetrical with respect to a center (center of gravity) of each machining mark. If machining feed in the X direction is performed in a state where the machining shape of each machining mark by one pulse of laser is distorted as in the examples Sp2 and L2, the depth and width of the two rows of the trimming grooves G1 and the hollow groove G2 may become uneven. Accordingly, the irradiation position, the beam diameter or intensity of the first laser light L1 and the second laser light L2, the orientation of the first condenser lens 16, and the orientation of the second condenser lenses 18A and 18B are adjusted so that the machining shape of each machining mark by one pulse of laser is roughly symmetrical with respect to a center of each machining mark (center of gravity).

According to the example 3, the machining shape by a single pulse is adjusted, thereby correcting the split laser and the line laser more effectively.

In the example 3, for example, a white interference microscope may be used to measure the three-dimensional shape of the machining mark by one pulse of laser so as to be able to perform examination for machining depth, three-dimensional shape, and the like in advance, as well.

### Modifications

Note that in the above embodiment, the sub-table T2 is provided to hold the positioning workpiece W2, though the sub-table T2 may be omitted. Specifically, in place of the wafer W1 to be machined, the positioning workpiece W2 is loaded onto the table T1, and the positioning workpiece W2 is laser-machined using the first laser light L1 and the second laser light L2 to correct displacement of the machining position. Then, the wafer W1 to be machined is loaded onto the table T1 for laser machining.

According to the modification, the sub-table T2 may be omitted in correcting the displacement in the positions of the first laser light L1 and the second laser light L2.

### REFERENCE SIGNS LIST

1 . . . Laser machining device, 10 . . . Control device, 12A . . . First laser light source, 12B . . . Second laser light source, 14 . . . Laser optical system, 16 . . . First condenser lens, 18A, 18B . . . Second condenser lens, 20 . . . Microscope, 22 . . . Relative moving mechanism, T1 . . . Table, T2 . . . Sub-table

What is claimes is:

1. A laser light correction method, comprising:
a step of performing trimming machining on a positioning workpiece in which at least a laser irradiation surface includes a material that facilitates detection of a laser- irradiation mark, the trimming machining in which a split laser is focused on the laser irradiation surface via a laser optical system while moving the laser optical system in the machining feed direction relative to the positioning workpiece to form a first groove having two rows parallel to each other in a machining feed direction, and performing hollowing machining in which a line laser is focused on the laser irradiation surface via the laser optical system to form a second groove;
a step of detecting the first groove and the second groove by a microscope; and
a step of correcting focus positions of the split laser and the line laser based on detection results of the first groove and the second groove.

2. The laser light correction method according to claim 1, wherein
the positioning workpiece is a wafer with a polyimide film or alignment paper.

3. The laser light correction method according to claim 1, wherein
during the trimming machining and the hollowing machining, one of the split laser and the line laser is caused to scan the laser irradiation surface in the machining feed direction, and another of the split laser and the line laser is caused to scan the laser irradiation surface in an oblique direction with respect to the machining feed direction.

4. The laser light correction method according to claim 1, wherein
the split laser and the line laser are caused to focus on the positioning workpiece as single pulse lasers.

5. The laser light correction method according to claim 1, wherein
an overlapping ratio between the split laser and the line laser on the laser irradiation surface is set to zero.

6. The laser light correction method according to claim 1, wherein
at least two alignment marks are formed on the positioning workpiece in the machining feed direction, and
the focus positions of the split laser and the line laser are corrected based on detection results of the alignment marks, and the first groove and the second groove.

7. The laser light correction method according to claim 1, wherein
the positioning workpiece is held on a sub-table different from a table for holding a workpiece to be machined.
